(19) United States
(12) Patent Application Publication
(10) Pub. No.: US 2026/0156906 A1
(43) Pub. Date: Jun. 4, 2026

(54) METHODS OF FORMING SOURCE/DRAIN REGIONS AND OVERLYING DIELECTRIC LAYERS IN CFETS

(71) Applicant: Taiwan Semiconductor Manufacturing Co., Ltd., Hsinchu (TW)

(72) Inventors: Che Chi Shih, Taoyuan City (TW); Yu-Hsien Chiang, Hsinchu (TW); Man-Nung Su, Taipei City (TW); Zhi-Chang Lin, Zhubei City (TW); Ku-Feng Yang, Baoshan Township (TW); Szuya Liao, Zhubei City (TW); Szu-Hua Chen, Tainan City (TW)

(21) Appl. No.: 19/181,603

(22) Filed: Apr. 17, 2025

Related U.S. Application Data
(60) Provisional application No. 63/727,842, filed on Dec. 4, 2024.

(51) Int. Cl. H10D 84/01; H10D 84/83

(52) U.S. Cl. CPC H10D 84/013; H10D 84/0151; H10D 84/832

(57) ABSTRACT

A method includes forming a lower semiconductor nanostructure and an upper semiconductor nanostructure, and forming a lower source/drain region comprising performing a first epitaxy process to grow a first and a second semiconductor isolation layer from the lower semiconductor nanostructure and the upper semiconductor nanostructure, respectively. The method further includes performing a second epitaxy process to grow an epitaxy semiconductor layer from the first semiconductor isolation layer through a bottom-up deposition process, etching the second semiconductor isolation layer to expose a sidewall of the upper semiconductor nanostructure, forming an upper source/drain region starting from the upper semiconductor nanostructure, and, at a time after the upper source/drain region is formed, forming a contact etch stop layer and an inter-layer dielectric in a space between the lower source/drain region and the upper source/drain region.

### PRIORITY CLAIM AND CROSS-REFERENCE

This application claims the benefit of the following provisionally filed U.S. Patent application: Application No. 63/727,842, filed on Dec. 4, 2024, and entitled “Method for Fabricating Semiconductor Device,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2-12, 13A, 13B, 14A, 14B, 15A, 15B, and 16 are views of intermediate stages in the fabrication of CFETs in accordance with some embodiments.

FIGS. 17-20 are views of intermediate stages in the fabrication of CFETs in accordance with some embodiments.

FIGS. 21-26 are views of intermediate stages in the fabrication of CFETs in accordance with some embodiments.

FIG. 27 illustrates a process flow for fabricating the CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) and the methods of forming the same are provided. In accordance with some embodiments, each CFET includes a lower source/drain region and an upper source/drain region overlapping the lower source/drain region. The formation of the lower source/drain region is performed without using a dielectric liner for masking the sidewalls of upper semiconductor nanostructures. Rather, process conditions are adjusted, combined with the use of etch-back processes to selectively form the lower source/drain region, while no upper source/drain region is formed on the exposed sidewalls of the upper semiconductor nanostructures.

In accordance with some embodiments, after the lower source/drain region is formed, a dielectric film is selectively formed to passivate the exposed surfaces of the lower source/drain region. The formation process may include a plasma treatment process. The dielectric film is not formed on the sidewalls of the upper semiconductor nanostructures. An upper source/drain region may then be formed, and is spaced apart from the lower source/drain region by a space. The space between the lower source/drain region and the upper source/drain region may then be filled with a lower Contact Etch Stop Layer (CESL) and a lower Inter-Layer Dielectric (ILD).

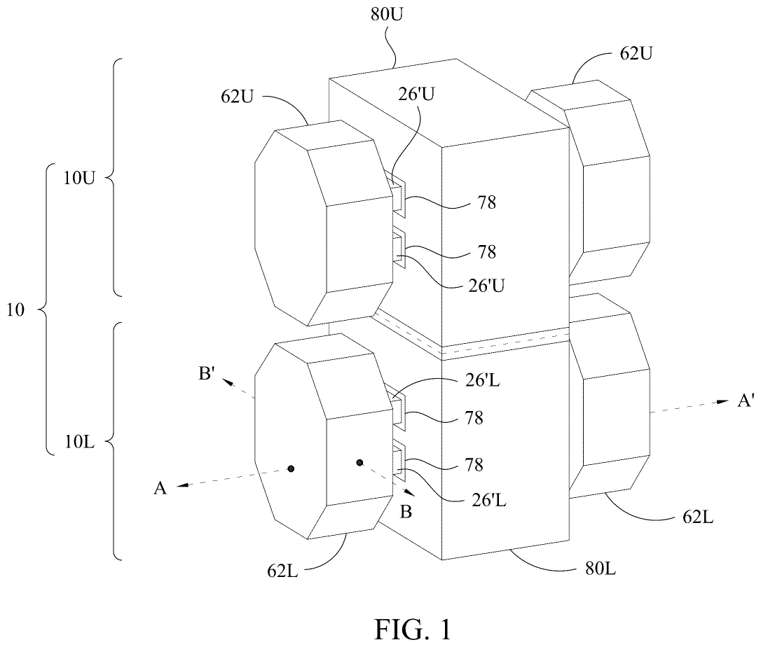

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

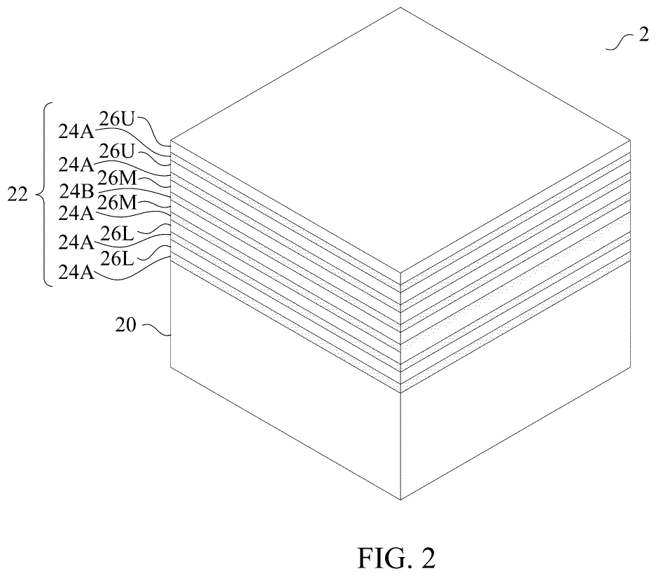

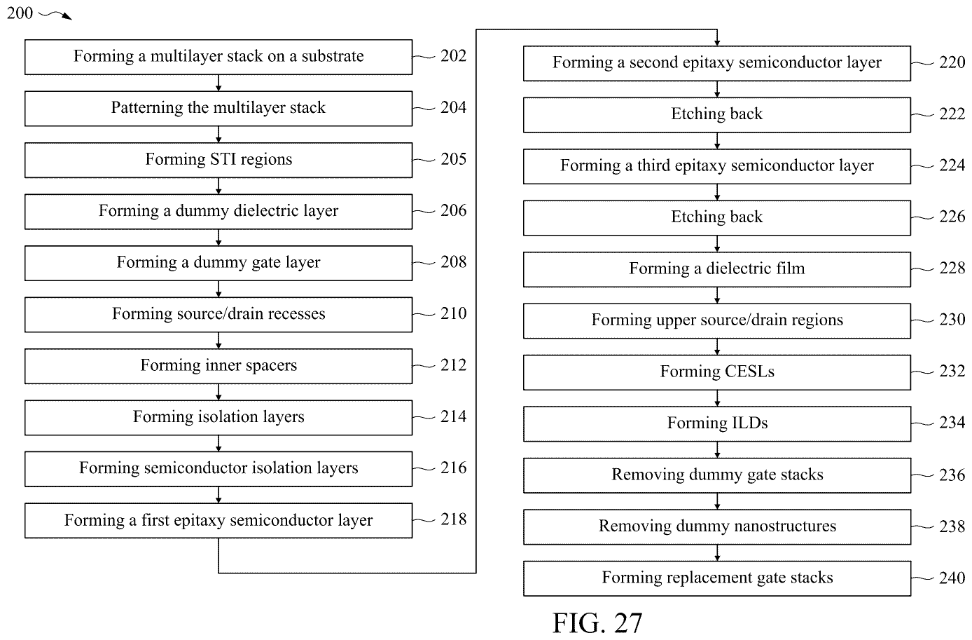

FIGS. 2 through 16 illustrate the cross-sectional views of intermediate stages in the formation of CFETs (as schematically represented in FIG. 1) in accordance with some embodiments. The corresponding processes are also reflected schematically in the process flow 200 as shown in FIG. 27. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor; or the like, or combinations thereof.

A multilayer stack 22 is formed over the substrate 20. The respective process is illustrated as process 202 in the process flow 200 as shown in FIG. 27. The multilayer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multilayer stack 22 includes six of the dummy semiconductor layers 24 and six of the semiconductor layers 26. It should be appreciated that the multilayer stack 22 may include any number of the dummy semiconductor layers 24 and the semiconductor layers 26. Each layer of the multilayer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

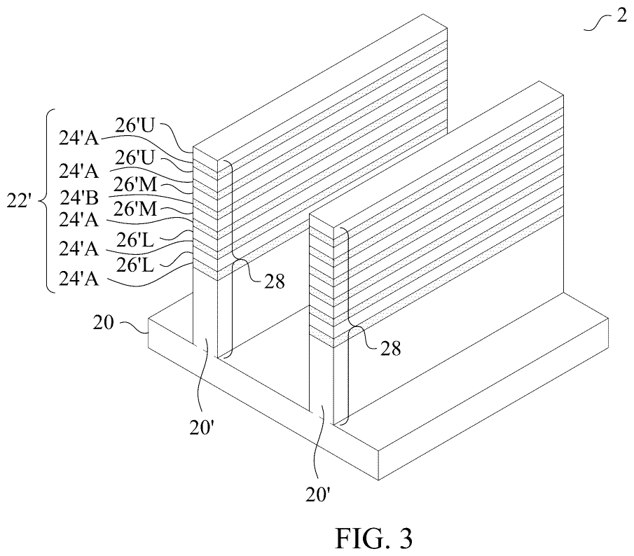

In FIG. 3, multilayer stack 22 and substrate 20 are patterned to form semiconductor strips 28. The respective process is illustrated as process 204 in the process flow 200 as shown in FIG. 27. Each of semiconductor strips 28 includes semiconductor strip 20′ (the portions of the original substrate 20) and multilayer stack 22′, which is the remaining portion of multilayer stack 22. The remaining portions 22′ of multilayers stack 22 are referred to as nanostructures hereinafter, which are referred to using the corresponding reference number followed by a “′” sign. Accordingly, multilayer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

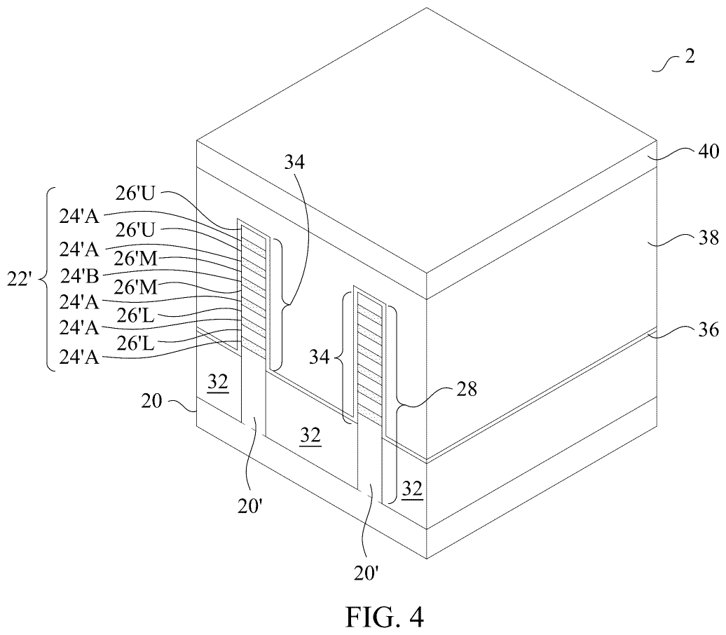

In FIG. 4, isolation regions 32 are formed over the substrate 20 and between adjacent semiconductor strips 28. The respective process is illustrated as process 205 in the process flow 200 as shown in FIG. 27. Isolation regions 32 may include a dielectric liner and a dielectric material over the dielectric liner. Isolation regions 32 are then recessed. Some upper portions of semiconductor strips 28 (including multilayer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 27. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 27. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

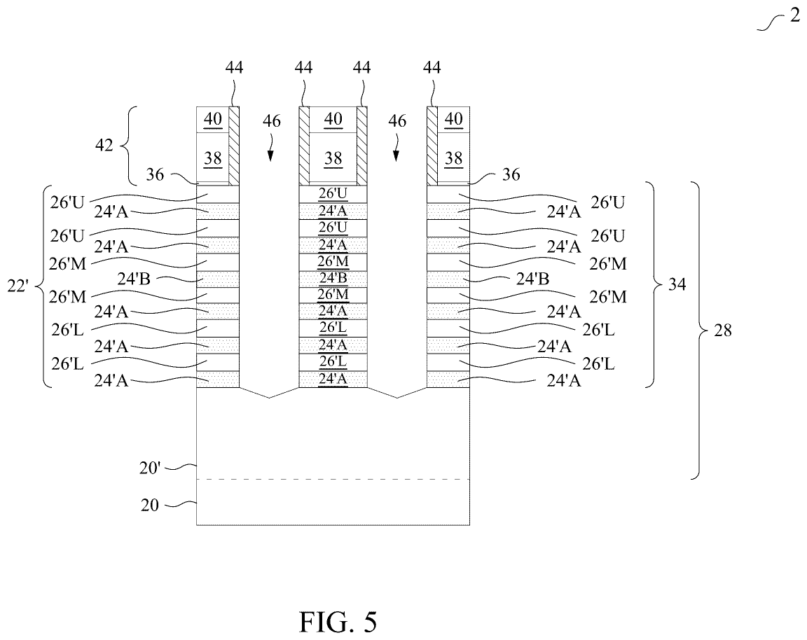

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multilayer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxycarbide, silicon oxynitride, silicon oxy-carbonitride, or the like, which may be formed by a deposition process such as CVD, ALD, or the like.

Source/drain recesses 46 are then formed in semiconductor strips 28. The respective process is illustrated as process 210 in the process flow 200 as shown in FIG. 27. The source/drain recesses 46 are formed through etching, and may extend through the multilayer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

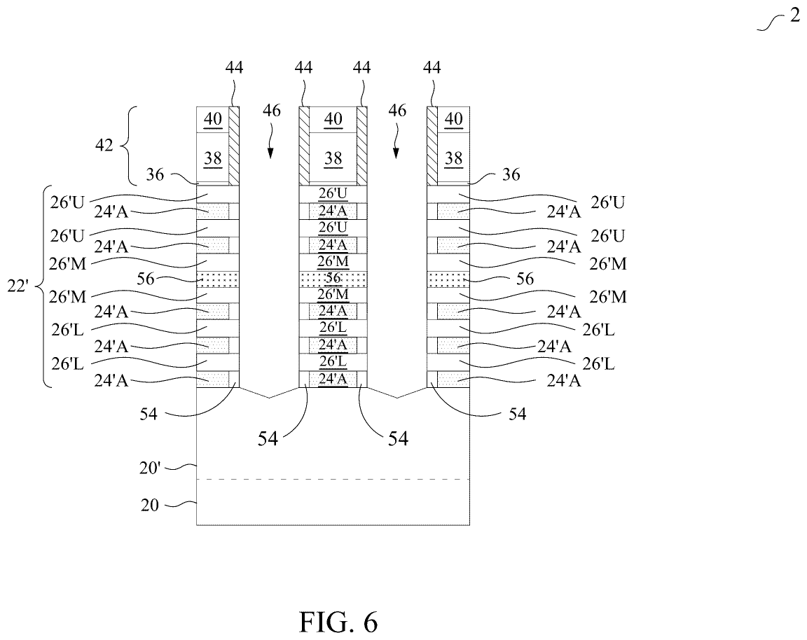

Dummy nanostructures 24′A are then laterally recessed, and a dielectric material is filled into the respective recesses to form inner spacers 54, which are dielectric spacers. The respective process is illustrated as process 212 in the process flow 200 as shown in FIG. 27. The resulting structure is shown in FIG. 6. In accordance with some embodiments, inner spacers 54 comprises nitrogen, and may be formed of or comprise SiN, SiON, SiCN, SiOCN, or the like. When comprising SiON or SiOCN, the nitrogen atomic percentage may be greater than the oxygen atomic percentage. When comprising carbon, the carbon atomic percentage may be smaller than about 6 percent. The material of inner spacers 54 may be a low-k dielectric material or a non-low-k dielectric material.

Dielectric isolation layers 56 are also formed to replace the dummy nanostructures 24′B. The respective process is illustrated as process 214 in the process flow 200 as shown in FIG. 27. The formation process may include etching dummy semiconductor layers 24′B (FIG. 5) to form recesses, and filling the recesses with a dielectric material to form dielectric isolation layers. The sequence for forming the inner spacers 54 and dielectric isolation layers 56 may be inversed.

In accordance with some embodiments, dielectric isolation layers 56 comprises oxygen, and may be formed of or comprise SiO, SiON, SiOC, SiOCN, AlO, TiO, or the like. When comprising carbon, the carbon atomic percentage may be smaller than about 6 percent. The material of dielectric isolation layers 56 may be a low-k dielectric material or a non-low-k dielectric material.

The oxygen atomic percentage of dielectric isolation layers 56 cannot be too high or too low. When the oxygen atomic percentage is smaller than about 20 percent, a semiconductor material may undesirably grow on dielectric isolation layers 56 in subsequent processes, resulting in large epitaxy semiconductor layers that are difficult to remove. When the oxygen atomic percentage is greater than about 70 percent, dielectric isolation layers 56 are more likely to be consumed in subsequent etching processes. In accordance with some embodiments, the oxygen atomic percentage of dielectric isolation layers 56 is in the range between about 20 percent and about 70 percent.

The oxygen atomic percentage of dielectric isolation layers 56 is greater than the oxygen atomic percentage of inner spacers 54. Also, the nitrogen atomic percentage of inner spacers 54 is greater than the nitrogen atomic percentage of dielectric isolation layers 56. Alternatively stated, the property of dielectric isolation layers 56 is more toward oxide than inner spacers 54, and the property of inner spacers 54 is more toward nitride than dielectric isolation layers 56. This will advantageously reduce the epitaxy of semiconductor on the surfaces of dielectric isolation layers 56 more than on the surfaces of inner spacers 54.

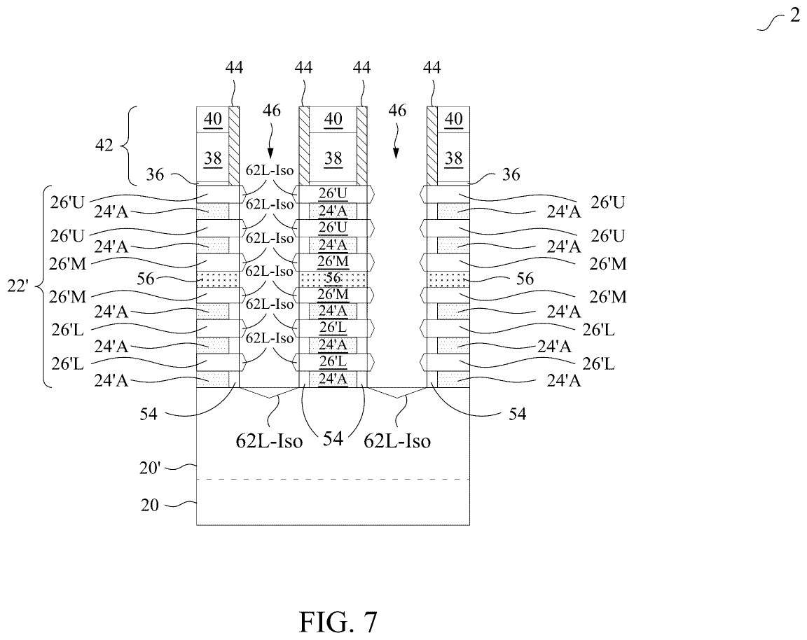

FIGS. 7-12 illustrate the unmasked formation of lower source/drain regions 62L in accordance with some embodiments. These embodiments are performed without forming dielectric liners to mask upper semiconductor nanostructures 26′U.

Referring to FIG. 7, epitaxy semiconductor layer 62L-Iso is formed through epitaxy. The respective process is illustrated as process 216 in the process flow 200 as shown in FIG. 27. It is appreciated that epitaxy semiconductor layers throughout the description may include a plurality of discrete portions that are separated from each other, which portions may be alternatively referred to as a plurality of semiconductor layers.

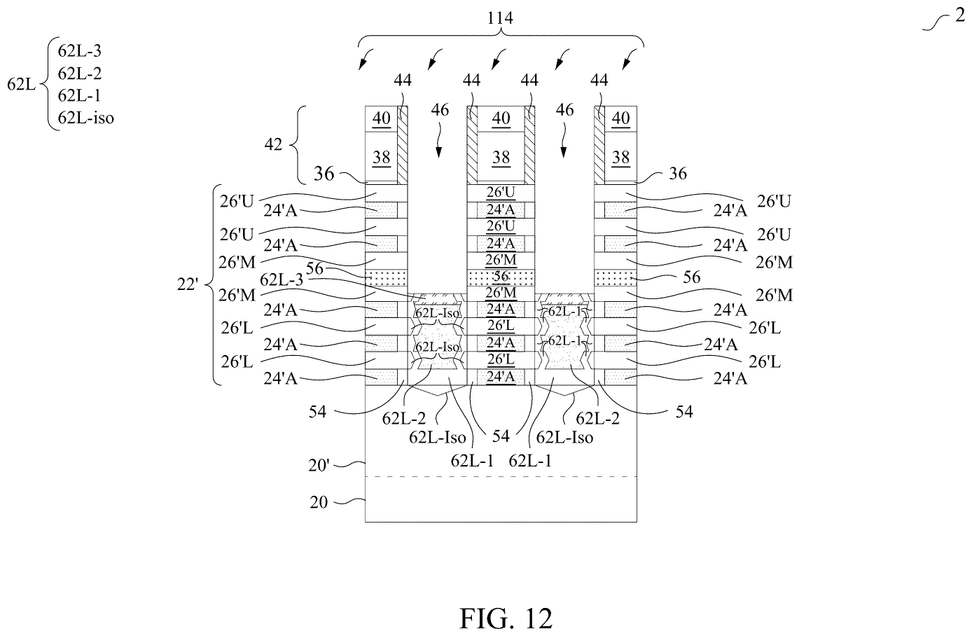

In accordance with some embodiments, the lower source/drain regions 62L (FIG. 12) are p-type semiconductor regions, and thus may comprise a p-type dopant such as boron, indium, and/or the like. Accordingly, epitaxy semiconductor layer 62L-Iso may comprise SiB, SiGeB, or the like. In accordance with alternative embodiments, the lower source/drain regions 62L are n-type semiconductor regions. In the following discussion, it is assumed that lower source/drain regions 62L are p-type regions. The formation of n-type source/drain regions 62L may also be realized from the discussion of the formation of the p-type lower source/drain regions 62L.

In accordance with some embodiments, epitaxy semiconductor layer 62L-Iso comprise silicon and free from germanium. Accordingly, Epitaxy semiconductor layer 62L-Iso may comprise SiB.

In accordance with alternative embodiments, epitaxy semiconductor layer 62L-Iso may comprise SiGeB. When comprising SiGeB, the germanium atomic percentage of epitaxy semiconductor layer 62L-Iso is lower than the germanium atomic percentage of dummy nanostructures 24′A, for example, with a difference in germanium atomic percentages being greater than about 20 percent or more. By having a large difference in germanium atomic percentages, in the subsequent removal of the dummy nanostructures 24′A, if inner spacers 54 have any damage, and epitaxy semiconductor layer 62L-Iso is exposed to the respective etching chemical, epitaxy semiconductor layer 62L-Iso may act as an isolation layer for stopping the lower source/drain regions from being damaged.

In accordance with some embodiments, the germanium atomic percentage of epitaxy semiconductor layer 62L-Iso is lower than about 50 percent, and may be in the range between about 10 percent and about 50 percent. The boron concentration in epitaxy semiconductor layer 62L-Iso may be in the range between about 1E20/cm³ and about 5E21/cm³.

In the epitaxy of epitaxy semiconductor layer 62L-Iso, a silicon-containing precursor such as silane, di-silane, dicholorosilane (DCS), or the like may be used. When epitaxy semiconductor layer 62L-Iso comprises germanium, a germanium-containing precursor such as germane, di-germane, or the like may be used. An etching gas such as HCl may also be added, so that the portions of epitaxy semiconductor layer 62L-Iso grown on exposed dielectric materials are etched.

Throughout the description, the conduction of the silicon-containing precursors results in epitaxy semiconductor layer 62L-Iso to be deposited at a deposition rate (assume no etching gas is conducted), which is the increase of thickness per unit time. The conduction of the etching gas causes the epitaxy semiconductor layers to be etched (assume no deposition is performed) at an etching rate, which is the decrease of thickness per unit time. The gross deposition rate equals to the deposition rate minus the etching rate, and an etching-to-deposition (rate) ratio (ED ratio) EDR is defined as the ratio of the etching rate to the deposition rate.

In the epitaxy of epitaxy semiconductor layer 62L-Iso, the ED ratio EDR-Iso is controlled to be high enough to remove the growth on dielectric materials such as inner spacers 54 and dielectric isolation layers 56, and low enough to not to cause bottom-up growth. For example, the ED ratio EDR-Iso may be in the range between about 0.2 and about 0.25, and may be in the range between about 0.1 and about 0.2.

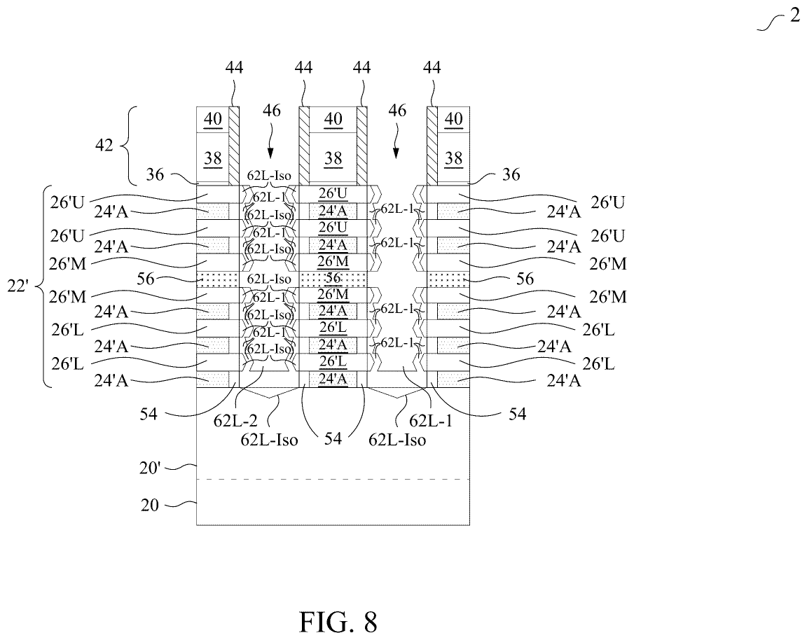

Referring to FIG. 8, epitaxy semiconductor layer 62L-1 (also) is formed through epitaxy. The respective process is illustrated as process 218 in the process flow 200 as shown in FIG. 27. Epitaxy semiconductor layer 62L-1 may comprise SiGeB. The germanium atomic percentage of epitaxy semiconductor layer 62L-1 is greater than the germanium atomic percentage of epitaxy semiconductor layer 62L-Iso. For example, the germanium atomic percentage of epitaxy semiconductor layer 62L-1 may be in the range between about 10 percent and about 60 percent. The boron concentration in epitaxy semiconductor layer 62L-Iso may be in the range between about 1E20/cm³ and about 5E21/cm³.

In the epitaxy of epitaxy semiconductor layer 62L-1, a silicon-containing precursor and a germanium-containing precursor are conducted. The silicon-containing precursor and the germanium-containing precursor may be selected from the same groups of candidate precursors used for forming epitaxy semiconductor layer 62L-Iso.

An etching gas such as HCl may also be added, so that the portions of epitaxy semiconductor layer 62L-1 grown on some of the exposed dielectric materials such as inner spacers 54 may have a low growth rate. Since the dielectric isolation layers 56 are formed of a material that is more oxide-based than inner spacers 54, the higher oxygen content passivates the surfaces of dielectric isolation layers 56. The growth on the oxide-based dielectric material is slower than on the nitride-based dielectric material of inner spacers. In accordance with some embodiments, the flow rate of the etching gas is adjusted so that no epitaxy semiconductor layer 62L-1 is grown on dielectric isolation layers 56, but some parts of epitaxy semiconductor layer 62L-1 are grown on inner spacers 54.

In the epitaxy of epitaxy semiconductor layer 62L-1, the ED ratio EDR1 is greater than the ED ratio ERD-iso for forming epitaxy semiconductor layer 62L-Iso. For example, the ED ratio EDR1 may be greater than about 0.25, and may be in the range between about 0.25 and about 0.4. Accordingly, the growth of epitaxy semiconductor layer 62L-1 on dielectric materials such as inner spacers 54 is low, but there is still a thin layer of epitaxy semiconductor layer 62L-1 grown on the inner spacers 54. This thin layer may act as a base for the subsequent formation of epitaxy semiconductor layer 62L-2.

In accordance with some embodiments, the substrate 20 has a (001) top surface orientation. The growth rate of epitaxy semiconductor layer 62L-1 in the (001) direction (pointing upwardly) is greater than the growth rate of epitaxy semiconductor layer 62L-1 in (111) directions, wherein the growth in the (111) directions are caused by the lateral growth. Accordingly, the epitaxy semiconductor layer 62L-1 is prone to be grown faster in the upward direction than in lateral directions. This combined with high ED ratio EDR1 results in the lateral growth to be suppressed, and the gross effect is more bottom-up growth than lateral growth.

Accordingly, the thickness of the bottom portions of epitaxy semiconductor layer 62L-1 at the bottoms of source/drain recesses 46 are thicker than the lateral-grown portions of epitaxy semiconductor layer 62L-1. Further due to the high ED ratio EDR1 and the lower growth on oxide-based dielectric isolation layers 56, no epitaxy semiconductor layer 62L-1 is grown on oxide-based dielectric isolation layers 56.

After the formation of epitaxy semiconductor layer 62L-1 and before the subsequent formation of epitaxy semiconductor layer 62L-2, no etch-back process is performed. Otherwise, the thin epitaxy semiconductor layer 62L-1 on the inner spacers 54 will be adversely removed.

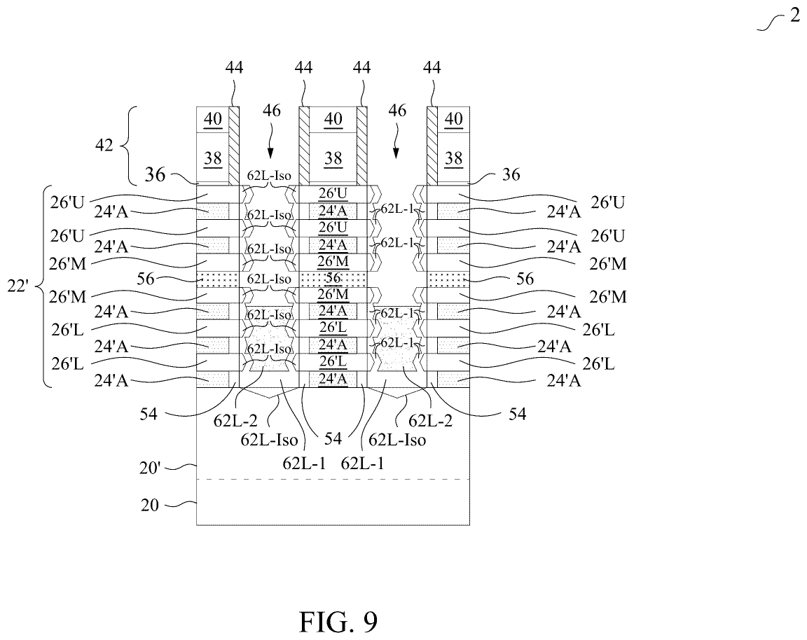

Referring to FIG. 9, epitaxy semiconductor layer 62L-2 is formed through epitaxy. The respective process is illustrated as process 220 in the process flow 200 as shown in FIG. 27. Epitaxy semiconductor layer 62L-2 may comprise SiGeB or GeB. The germanium atomic percentage of epitaxy semiconductor layer 62L-2 is greater than the germanium atomic percentage of epitaxy semiconductor layer 62L-1. For example, the germanium atomic percentage of epitaxy semiconductor layer 62L-2 may be in the range between about 30 percent and about 100 percent. The boron concentration in epitaxy semiconductor layer 62L-2 may be in the range between about 1E20/cm³ and about 5E21/cm³.

In the epitaxy of epitaxy semiconductor layer 62L-2, a silicon-containing precursor and a germanium-containing precursor are conducted. The silicon-containing precursor and the germanium-containing precursor may be selected from the same groups of candidate precursors used for forming epitaxy semiconductor layer 62L-Iso.

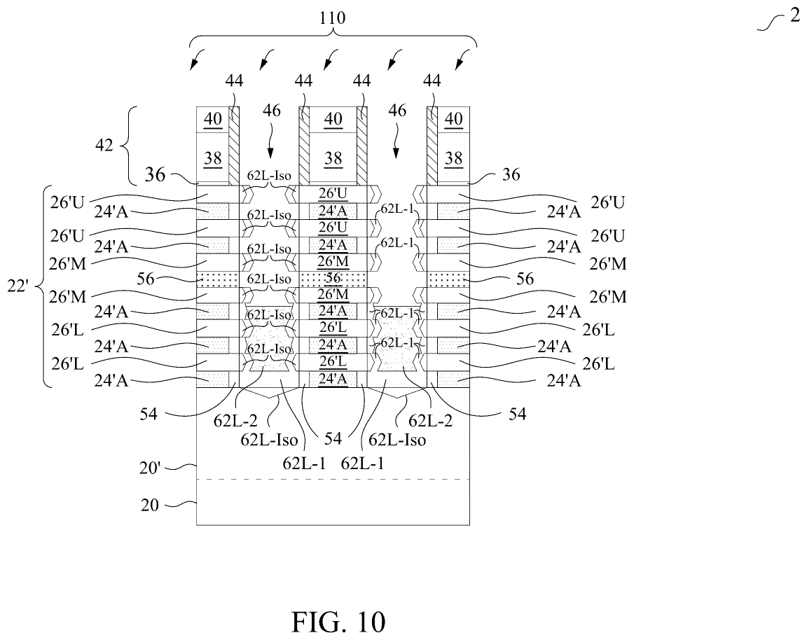

An etching gas such as HCl may also be added, so that the portions of epitaxy semiconductor layer 62L-2 grown on dielectric material are etched, and epitaxy semiconductor layer 62L-2 is selectively grown. There may not be epitaxy semiconductor layer 62-iso, 62L-1, and 62L-2 grown on the exposed dielectric isolation layers 56. This advantageously results in the epitaxy semiconductor layers 62L-Iso, and 62L-1, and 62L-2 to be separated into smaller portions, including the portion higher than dielectric isolation layers 56 and the portions lower than the dielectric isolation layers 56. Accordingly, in subsequent etch-back process 110 (FIG. 10), it is easier to remove the epitaxy semiconductor materials.

In the epitaxy of epitaxy semiconductor layer 62L-2, the ED ratio EDR2 is further higher than the ED ratio ER1 for forming epitaxy semiconductor layer 62L-1. For example, the ED ratio EDR2 may be greater than about 0.3, and may be in the range between about 0.3 and about 0.5. The higher ED ratio EDR2 combined with the higher growth rate in (001) direction results in the bottom-up growth of epitaxy semiconductor layer 62L-2.

Referring to FIG. 10, after the formation of epitaxy semiconductor layer 62L-2, a separate etch-back process 110 is performed. The respective process is illustrated as process 222 in the process flow 200 as shown in FIG. 27. In the etch-back process, an etching gas such as HCl is conducted, and no silicon-containing precursor and germanium-containing precursor are conducted. Accordingly, the portions of epitaxy semiconductor layer 62L-2 on inner spacers 54 (which portions of epitaxy semiconductor layer 62L-2 are thin) are removed.

In accordance with some embodiments, the etch-back process 110 results in the portions of epitaxy semiconductor layer 62L-2 higher than dielectric isolation layers 56 to be removed, while there are some portions of epitaxy semiconductor layer 62L-Iso and 62L-1 higher than dielectric isolation layers 56 remaining. In accordance with alternative embodiments, the etch-back process 110 results in all portions of epitaxy semiconductor layer 62L-Iso and 62L-1 and 62L-2 higher than dielectric isolation layers 56 to be removed.

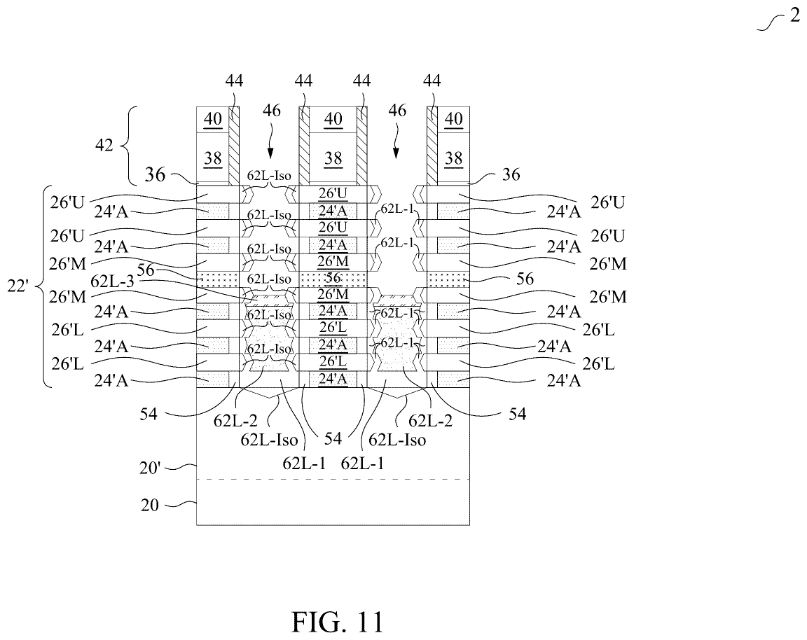

Referring to FIG. 11, epitaxy semiconductor layer 62L-3 is formed through epitaxy. The respective process is illustrated as process 224 in the process flow 200 as shown in FIG. 27. Epitaxy semiconductor layer 62L-3 may comprise SiGeB or SiB. The germanium atomic percentage of epitaxy semiconductor layer 62L-3 is lower than the germanium atomic percentage of epitaxy semiconductor layer 62L-2. For example, the germanium atomic percentage of epitaxy semiconductor layer 62L-2 may be lower than about 50 percent, and may be in the range between about 10 percent and about 50 percent, or between about 0 percent and about 10 percent. The boron concentration in epitaxy semiconductor layer 62L-Iso may be in the range between about 1E20/cm³ and about 5E21/cm³.

In the epitaxy of epitaxy semiconductor layer 62L-2, a silicon-containing precursor (and a germanium-containing precursor if SiGeB is formed) are conducted. The silicon-containing precursor and the germanium-containing precursor may be selected from the same groups of candidate precursors used for forming epitaxy semiconductor layer 62L-Iso.

An etching gas such as HCl may also be added, so that the portions of epitaxy semiconductor layer 62L-3 grown on exposed dielectric materials are etched, and epitaxy semiconductor layer 62L-3 is grown selectively. In the epitaxy of epitaxy semiconductor layer 62L-3, the ED ratio EDR3 is lower than the ED ratio ER1 for forming epitaxy semiconductor layer 62L-1 and the ED ratio ER2 for forming epitaxy semiconductor layer 62L-2.

After the formation of epitaxy semiconductor layer 62L-3, an etch-back process 114 is performed, so that the epitaxy materials on exposed portions of inner spacers 54 and dielectric isolation layers 56 (if any) are all removed. The respective process is illustrated as process 226 in the process flow 200 as shown in FIG. 27. The exposed portions of epitaxy semiconductor layers 62L-1 and 62L-iso are also removed. The resulting structure is shown in FIG. 12.

In accordance with some embodiments, epitaxy semiconductor layer 62L-3 may be used as the capping layer (which may be an etch stop layer) for forming contact plugs (not shown) that are used to connect lower source/drain regions 62L to overlying features such as metal lines and vias. Accordingly, the contact plugs may penetrate through epitaxy semiconductor layers 62L-3, and metal silicide layers may be formed on the top surfaces of epitaxy semiconductor layers 62L-2.

Epitaxy semiconductor layers 62L-Iso, 62L-1, 62L-2, and 62L-3 collectively form lower source/drain regions 62L. The top surfaces of lower source/drain regions 62L are lower than the bottom surface of dielectric isolation layers 56, and may be lower than, higher than, or level with the bottom surfaces of middle semiconductor nanostructures 26′M.

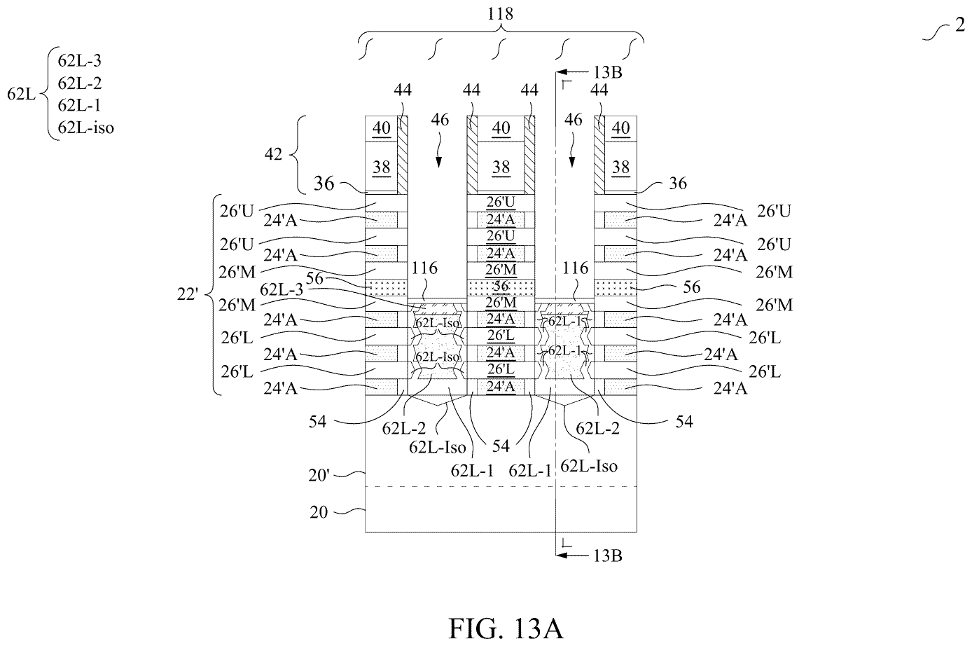

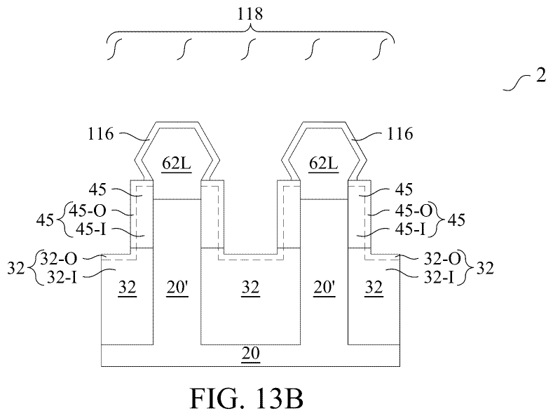

Referring to FIGS. 13A and 13B, dielectric film 116 is formed. The respective process is illustrated as process 228 in the process flow 200 as shown in FIG. 27. In accordance with some embodiments, dielectric film 116 is selectively formed on the exposed surfaces of lower source/drain regions 62L, and not on the sidewalls of semiconductor nanostructures 26′U.

FIG. 13B illustrates a cross-sectional view obtained from the cross-section 13B-13B in FIG. 13A. Fin spacers 45, STI regions 32, semiconductor strip 20′, and a top portion of semiconductor substrate 20 are illustrated.

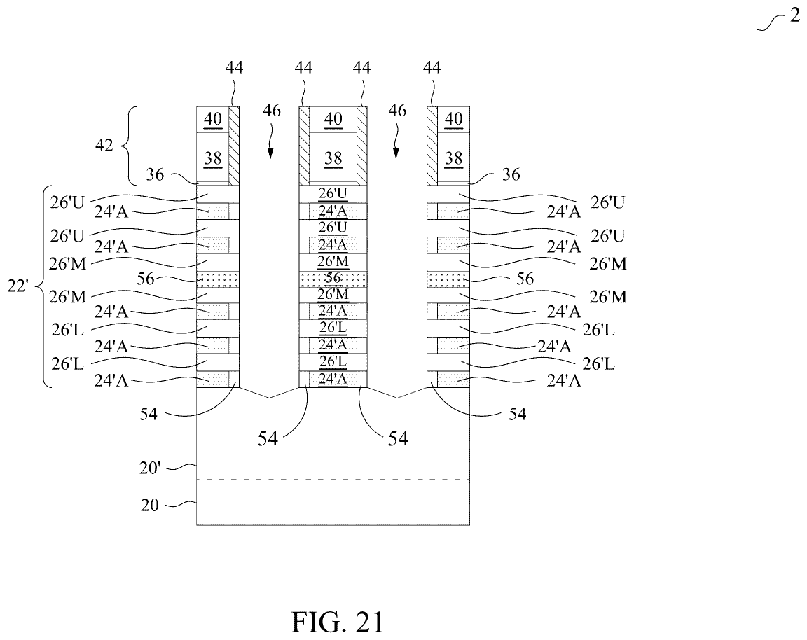

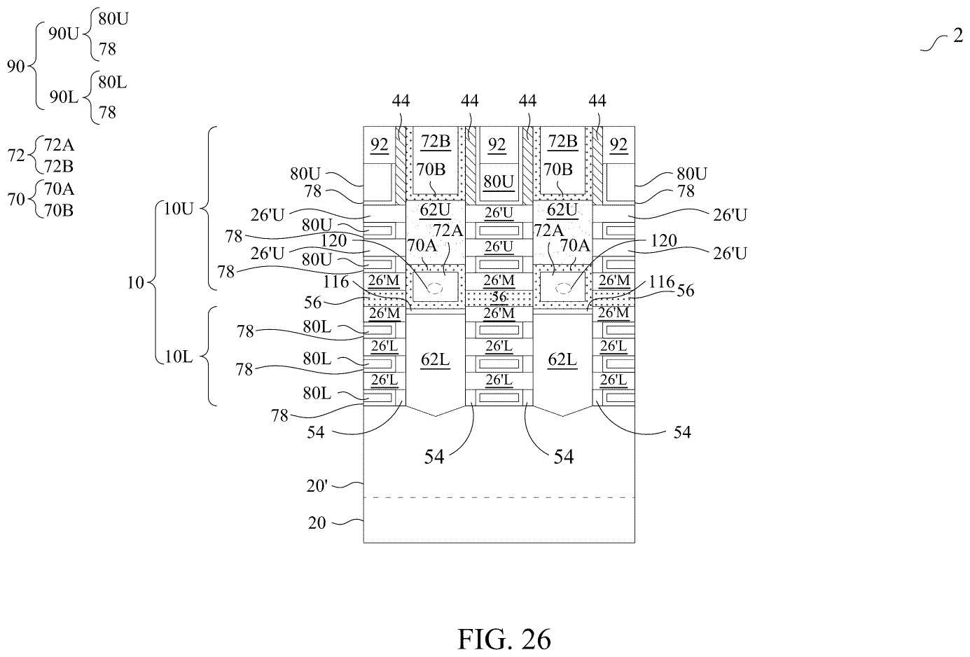

As shown in FIG. 13B, dielectric film 116 may be formed as a conformal or non-conformal layer, which comprises top portions on the top surfaces of lower source/drain region 62L, and sidewall portions on the sidewalls of lower source/drain region 62L. In accordance with some embodiments, lower source/drain region 62L are formed using the processes as shown in FIGS. 7-12. In accordance with alternative embodiments, lower source/drain region 62L may be formed using the processes as shown in FIGS. 21-26, and thus may have different structures that what is shown in FIG. 13A. Accordingly, in FIG. 13B, lower source/drain region 62L are schematically illustrated without showing details.

In accordance with some embodiments, the formation of dielectric film 116 may comprise a treatment process 118. The treatment process 118 may be performed using a process gas comprising an oxygen-containing gas, a nitrogen-containing gas, or a combination thereof. For example, the process gas may comprise ozone (O₃), oxygen (O₂), nitrogen (N₂), ammonia (NH₃), and/or the like. Inert gases such as argon may also be included in the process gas. The treatment process 118 may be performed at room temperature (for example, in the range between about 20° C. and about 25° C.), or at a slightly elevated temperature, for example, in the range between about 25° C. and about 80° C.

Plasma is generated from the process gas. In accordance with some embodiments, the plasma treatment process 118 comprises a plasma immersion process, in which a high-density plasma is used. The plasma may comprise ions and radicals, both being used for the treatment. The density of the plasma may be increased by increasing the pressure of the process gas and the source power to suit to the increased pressure of the process gas. The wafer 2 is thus immersed in the high-density plasma.

In the plasma treatment process 118, the surface portions of lower source/drain regions 62L react with the elements in the plasma, so that dielectric film 116 is formed. Accordingly, dielectric film 116 comprises the elements in the exposed portions of lower source/drain regions 62L and the elements in the plasma. In accordance with some embodiments in which the lower source/drain regions 62L have the structure as shown in FIG. 13A, dielectric film 116 comprises the elements of epitaxy semiconductor layers 62L-3 (such as silicon and boron, and possibly germanium), and the elements in the plasma such as oxygen, nitrogen, argon, or combinations thereof. The resulting dielectric film 116 thus may comprise, SiO, SiN, SiON, SiGeO, SiGeN, SiGeON, or the like, and may have boron and argon doped therein.

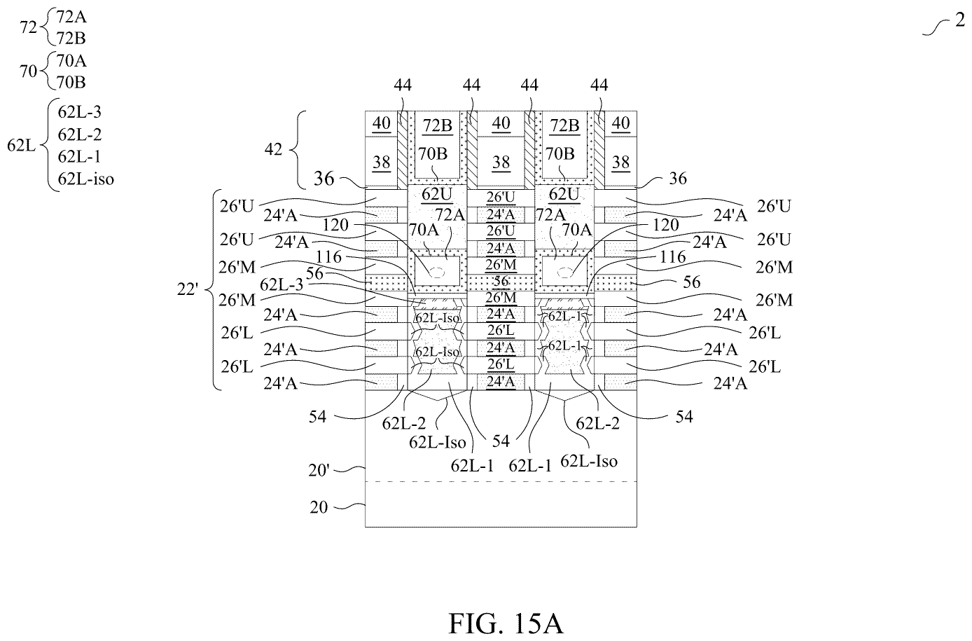

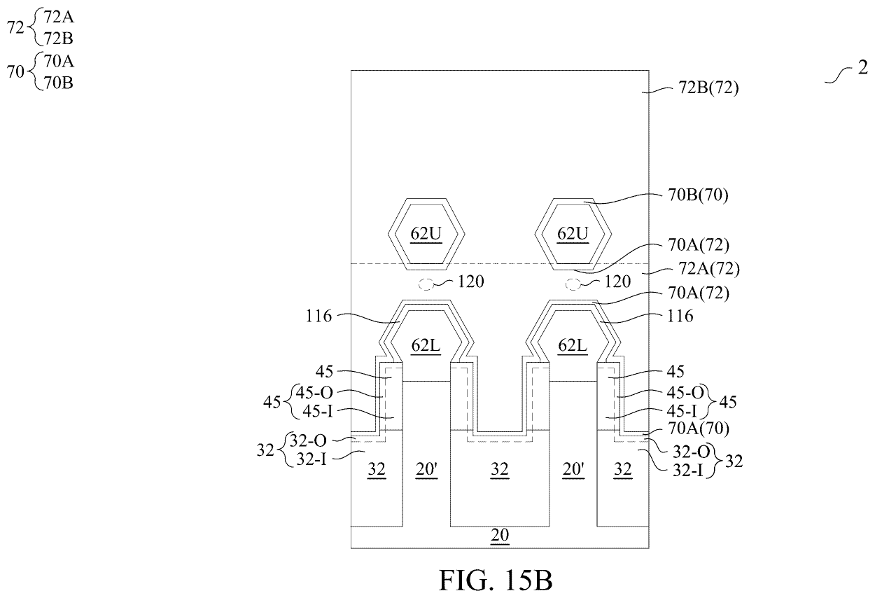

Dielectric film 116 may have a thickness in the range between about 1 nm and about 3 nm. If the dielectric film 116 is too thick such as thicker than 3 nm, the subsequently deposited ILD 72A (FIGS. 15A and 15B) may not be able to be filled into the space between lower source/drain regions 62L and upper source/drain regions 62U. if the dielectric film 116 is too thin such as thinner than 1 nm, dielectric film 116 may not be able to passivate the surfaces of lower source/drain regions 62L, and the materials of the upper source/drain regions 62U may be adversely grown starting from lower source/drain regions 62L.

It is appreciated that the sidewalls of semiconductor nanostructures 26′U are also exposed during the plasma treatment process 118. In accordance with some embodiments, the process condition of the plasma treatment process 118 is adjusted, so that dielectric film 116 is selectively formed on lower source/drain regions 62L, but not on the exposed sidewalls of semiconductor nanostructures 26′U. Alternatively, on the exposed sidewalls of semiconductor nanostructures 26′U, dielectric film 116 is formed, but is very thin (thinner than 1 nm or 0.5 nm), so that upper source/drain regions 62U may still be grown starting from semiconductor nanostructures 26′U. The thin dielectric film 116, if formed, may be removed, as discussed in subsequent paragraphs.

In accordance with some embodiments, a low bias power is applied, which is high enough so that the formation of dielectric film 116 is directional. Accordingly, on the sidewalls of semiconductor nanostructures 26′U, which are not on the traveling path of the plasma, dielectric film 116 is not formed, or is formed but is thin enough and does not prevent the formation of upper source/drain regions 62U. The bias power is also low enough so that the top surfaces of lower source/drain regions 62L and the formed dielectric film 116 are not removed due to bombardment. In accordance with some embodiments, the bias power may be in the range between about 5 watts and about 20 watts.

The plasma treatment process 118 may also includes a first treatment process, in which no bias power is applied, or a lower bias power is applied, so that the dielectric film 116 is formed on all exposes surfaces of semiconductor materials, including the sidewalls of semiconductor nanostructures 26′U and the downward-facing facets of lower source/drain regions 62L. Process conditions may also be adjusted so that the portions of the dielectric film 116 on the top surfaces of lower source/drain region 62L have greater thicknesses than on the sidewalls of semiconductor nanostructures 26′U and on the downward-facing facets of lower source/drain regions 62L.

A second plasma treatment process 118 may then be performed, which may include a slant treatment with a bias power, and thus has a greater removal rate than formation rate. As a result, the portions of the dielectric film 116 on the sidewalls of semiconductor nanostructures 26′U are removed, while the portions of the dielectric film 116 on the downward facing facets of lower source/drain regions 62L are not removed due to the masking of the top portions of lower source/drain regions 62L. The portions of the dielectric film 116 on the top surfaces of lower source/drain regions 62L have portions remaining due to their greater thickness.

Due to the first and the second plasma treatment process 118, the portions of the dielectric film 116 on the top surfaces of lower source/drain regions 62L may have a thickness greater than, equal to, or smaller than, the portions of the dielectric film 116 on the downward-facing facets of lower source/drain regions 62L.

The dielectric materials whose surfaces are exposed to the plasma may have increased atomic percentage of the elements (in the treatment process gas) than the inner portions of respective dielectric materials due to the diffusion and mixing of the elements in the treatment process gas. For example, in FIG. 13B, fin spacers 45 include outer portions 45-O and inner portions 45-I. STI regions 32 include outer portions 32-O and inner portions 32-I. Depending on the elements in the treatment process gas, outer portions 45-O may have greater atomic percentage of oxygen and/or nitrogen (which is/are also in dielectric film 116) than inner portions 45-I. Outer portions 32-O may have greater atomic percentage of oxygen and/or nitrogen (which is/are also in dielectric film 116) than inner portions 32-I.

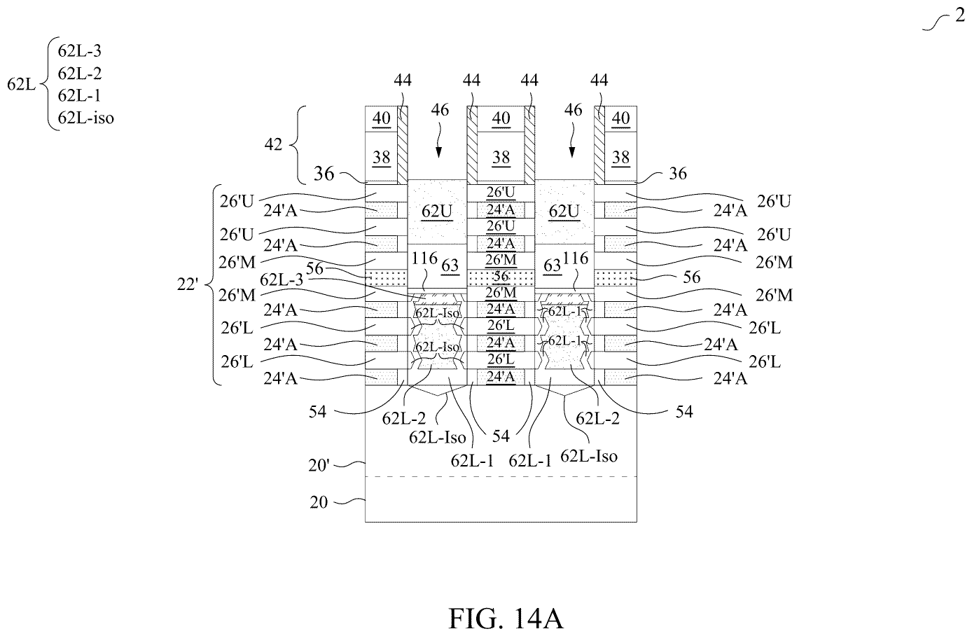

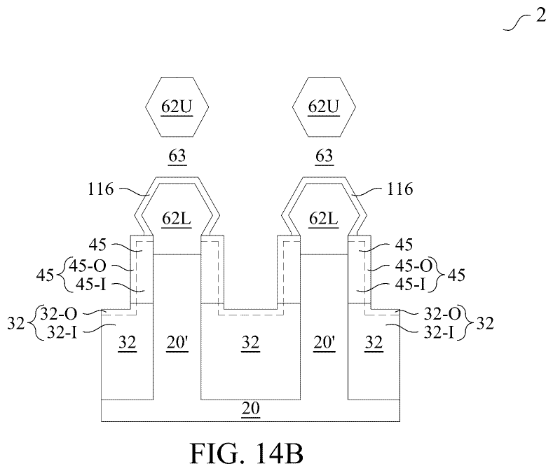

Referring to FIGS. 14A and 14B, upper epitaxial source/drain regions 62U are formed in the upper portions of the source/drain recesses 46. The respective process is illustrated as process 230 in the process flow 200 as shown in FIG. 27. The materials of upper epitaxial source/drain regions 62U may be selected from the same candidate group of materials for forming lower source/drain regions 62L, depending on the desired conductivity type of upper epitaxial source/drain regions 62U. Voids 63 are thus formed to separate upper epitaxial source/drain regions 62U from lower epitaxial source/drain regions 62L.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. In the embodiments in which the lower source/drain regions 62L comprise a p-type dopant, the upper source/drain regions 62U may comprise an n-type dopant such as phosphorous, arsenic, and/or the like.

The epitaxy of the upper epitaxial source/drain regions 62U is started from the sidewalls of the upper semiconductor nanostructures 26′U, and upper epitaxial source/drain regions 62U are grown laterally, until the portions of the upper epitaxial source/drain regions 62U that are grown in opposite directions merge with each other. The upper portions of the upper epitaxial source/drain regions 62U grown from the upper ones of the upper semiconductor nanostructures 26′U are also merged with the lower portions of the upper epitaxial source/drain regions 62U grown from the respective lower ones of the upper semiconductor nanostructures 26′U.

It is appreciated that the middle semiconductor nanostructures 26′M may not be formed, or may be formed, but are thinner than the upper semiconductor nanostructures 26′U, accordingly, the portions of the upper epitaxial source/drain regions 62U grown from the thin middle semiconductor nanostructures 26′M (if formed) would be small, and are not shown.

The upper epitaxial source/drain regions 62U are formed as being suspended, and spaces 63 (also referred to as air gaps) are located between the upper epitaxial source/drain regions 62U and the respective lower epitaxial source/drain regions 62L.

Next, as shown in FIGS. 15A and 15B, CESLs 70A and 70B (individually and collectively referred to as CESLs 70) are formed. The respective process is illustrated as process 232 in the process flow 200 as shown in FIG. 27. CESLs 70A and 70B are formed in a same formation process, and may be formed of a dielectric material having a high etching selectivity relative to the subsequently formed ILDs 72A and 72B. In accordance with some embodiments, CESLs 70A and 70B may be formed of or comprise as silicon nitride, silicon oxide, silicon oxynitride, or the like, which may be formed by any suitable conformal deposition process, such as CVD, ALD, or the like.

CESLs 70A and 70B may be formed of a same material as, or different materials than, dielectric film 116. CESLs 70A may be formed as full rings including top portions contacting the bottom surfaces of upper source/drain regions 62U, and bottom portions contacting the respective underlying dielectric films 116. Since the CESLs 70A and 70B may be conformal, the total thickness of the bottom portions of CESLs 70A and dielectric film 116 is greater than the top portions of CESLs 70A, and greater than the thickness of CESLs 70B.

After the formation of CESLs 70A and 70B, ILDs 72A and 72B (individually and collectively referred to as ILDs 72) are formed. The respective process is illustrated as process 234 in the process flow 200 as shown in FIG. 27. The ILDs 72A and 72B may be formed of a dielectric material, which may be deposited by any suitable method, such as ALD, CVD, plasma-enhanced CVD (PECVD), or FCVD. The applicable dielectric material of the ILDs 72A and 72B may include phospho-silicate glass (PSG), boro-silicate glass (BSG), boron-doped phospho-silicate glass (BPSG), undoped silicate glass (USG), silicon oxide, or the like.

ILDs 72A and 72B are formed sharing common formation processes, and are formed of the same material. The formation processes of the ILDs 72A and 72B may include a deposition process, followed by a planarization process. In FIG. 15B, a dashed line is drawn to schematically mark where CESLs 70A and 70B are joined, and where ILDs 72A and 72B are joined. It is appreciated that since CESLs 70A and 70B are formed in a same continuous process, and ILDs 72A and 72B are formed in the same continuous process, there is no distinguishable interface between CESLs 70A and 70B, and there is no distinguishable interface between ILDs 72A and 72B.

CESL 70A and ILD 72A fill voids 63. In accordance with some embodiments, the formation of ILDs 72A and 72B may be sealed pre-maturely, and voids (air gaps) 120 may be left at the centers of ILDs 72A. The voids 120 may be in the middle between the top portions and the bottom portions of CESLs 70A. Voids 120 may be elongated with lengthwise directions extending horizontally, and may have a lateral maximum dimension (maximum width) and a vertical maximum dimension (maximum height) smaller than the lateral dimension. In accordance with alternative embodiments, ILDs 72A have no voids formed therein. There may be, or may not be voids formed in ILDs 72B. When voids are formed in ILD 72B, the voids, which may be seams, may be elongated with lengthwise directions extending vertically.

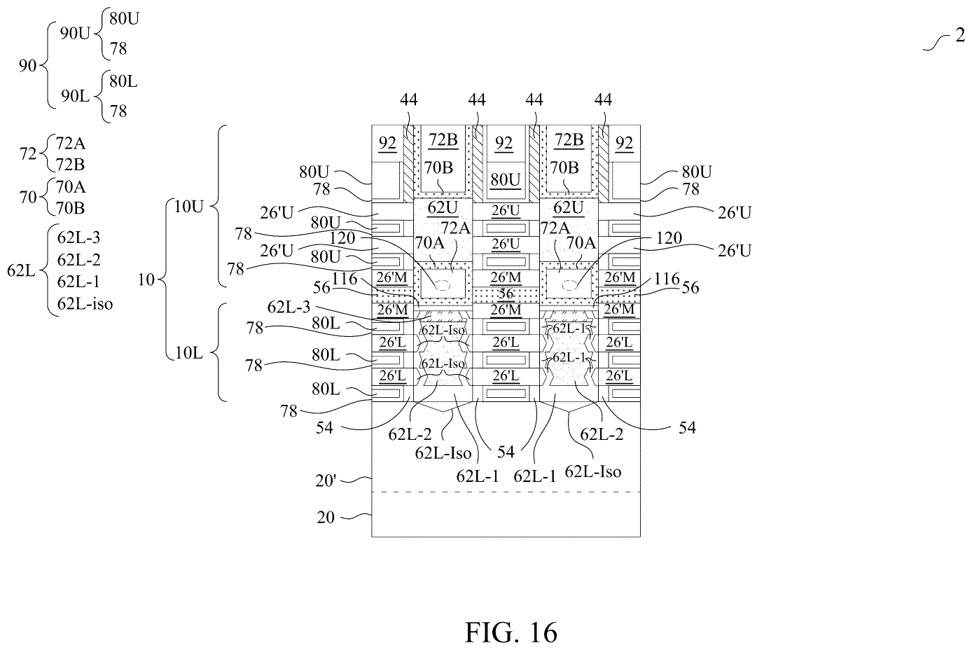

In subsequent processes, the dummy gate stacks 42 are removed in one or more etching processes, so that recesses (not shown, occupied by gate stacks 90 and dielectric hard masks 92 as shown in FIG. 16) are formed. The respective process is illustrated as process 236 in the process flow 200 as shown in FIG. 27.

The remaining portions of the dummy nanostructures 24′A (FIG. 15A) are then removed through etching, so that the recesses extend between the semiconductor nanostructures 26′. The respective process is illustrated as process 238 in the process flow 200 as shown in FIG. 27. In the etching process, the dummy nanostructures 24′A are etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

Gate dielectrics 78 are formed in the recesses and on the exposed surfaces of the exposed features including the semiconductor nanostructures 26′ and the gate spacers 44. The gate dielectrics 78 wrap around all (e.g., four) sides of the semiconductor nanostructures 26′. Each of the gate dielectrics 78 may include an interfacial layer, which may include an oxide such as silicon oxide. The interfacial layer may be formed through a thermal oxidation process and/or a deposition process. The gate dielectrics 78 may also include high-k dielectric layers, which have a high dielectric constant (high-k) value greater than, for example, about 7.0. High-k dielectric layers may be formed of or comprise a metal oxide or a silicate of a metal selected from hafnium, zirconium, barium, titanium, lead, and combinations thereof.

Gate electrodes 80L and 80U are also formed. In the formation process, conductive layers are first formed on the high-k dielectric layer, and the remaining portions of the recesses are filled. Each of gate electrode 80L and 80U may include a metal-containing material such as TiN, TaN, TiAl, TiAlC, cobalt, ruthenium, aluminum, tungsten, combinations thereof, and/or multilayers thereof. The gate electrodes 80L and 80U may provide work-functions suitable to the resulting lower FETs (lower transistors) 10L and upper FETs (upper transistors) 10U. The gate electrodes 80L and 80U may be common gates formed in a same formation process, or may be electrically disconnected from each other and formed in separate formation processes.

As shown in FIG. 16, gate dielectrics 78 and gate electrodes 80L collectively form (replacement) gate stacks 90L. Gate dielectrics 78 and gate electrodes 80U collectively form (replacement) gate stacks 90U. The respective process is illustrated as process 240 in the process flow 200 as shown in FIG. 27. CFET 10, which includes upper FETs 10U and lower FETs 10L, are thus formed.

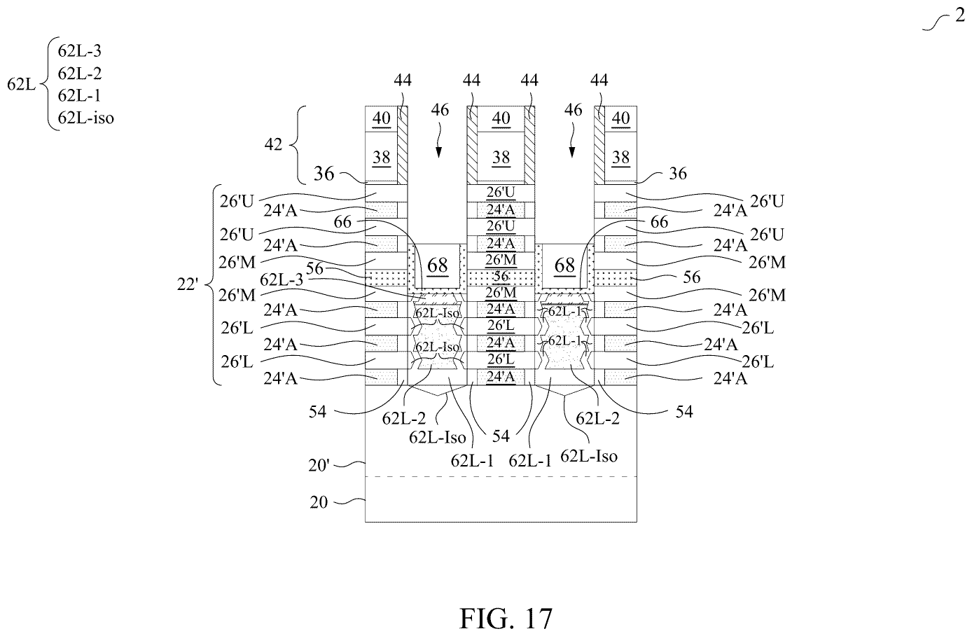

FIGS. 17 through 20 illustrate the cross-sectional views of intermediate stages in the formation of a CFET in accordance with alternative embodiments of the present disclosure. These embodiments are similar to the embodiments as shown in FIGS. 1 through 16, except that the CESLs, ILD, and upper source/drain regions are formed using different processes than in the preceding embodiments. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

The initial steps of these embodiments are essentially the same as shown in FIGS. 2 through 12. Next, as shown in FIG. 17, A first contact etch stop layer (CESL) 66 and a first ILD 68 are formed. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

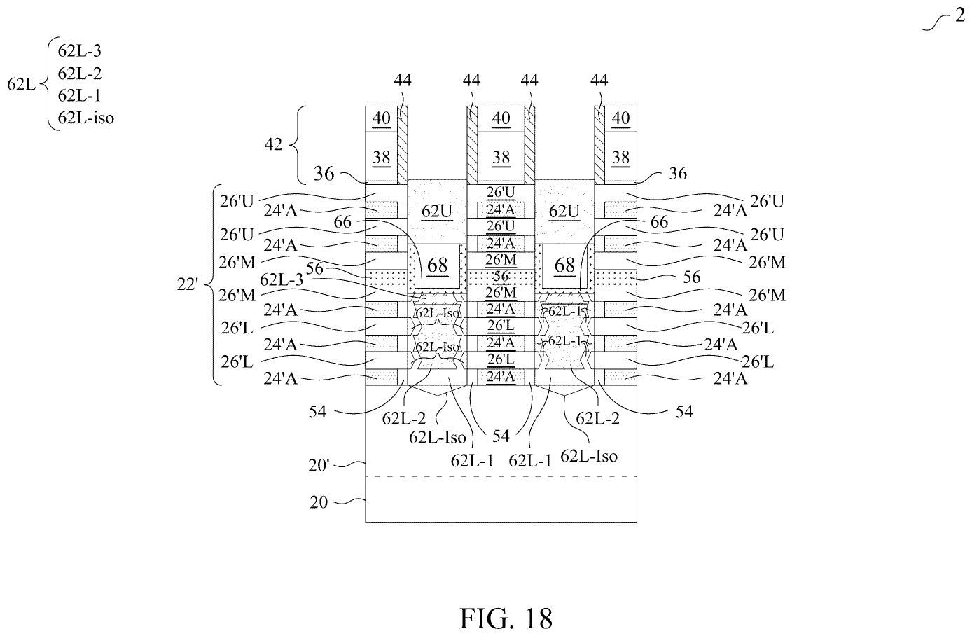

Next, as shown in FIG. 18, upper epitaxial source/drain regions 62U are formed in the upper portions of the source/drain recesses 46. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

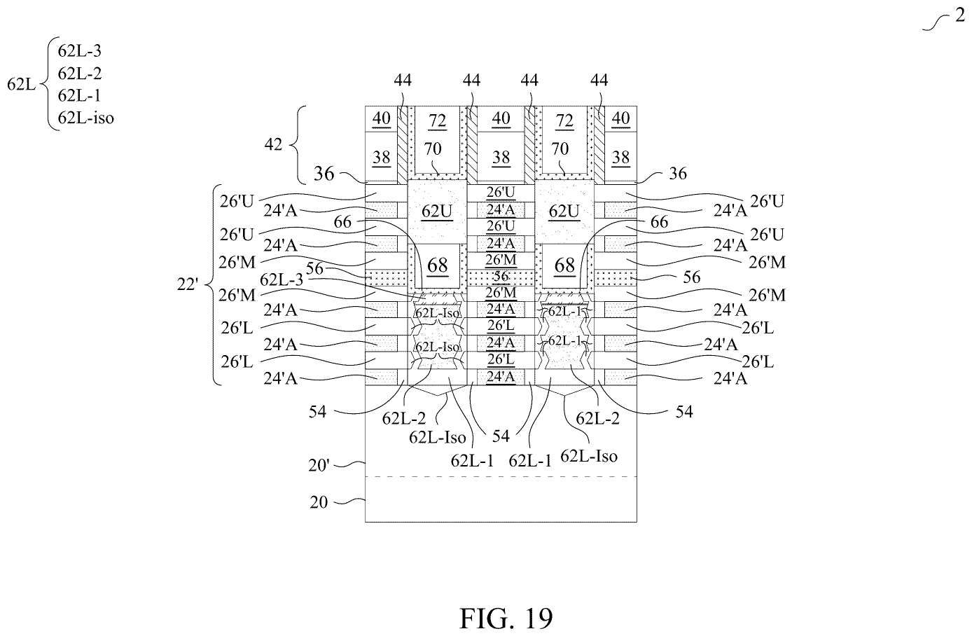

Next, as shown in FIG. 19, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

The dummy gate stacks 42 are then removed in one or more etching processes, so that recesses are formed. Each of the recesses exposes and/or overlies portions of multilayer stacks 22′. The remaining portions of the dummy nanostructures 24′A (FIG. 6) are then removed through etching, so that the recesses extend between the semiconductor nanostructures 26′.

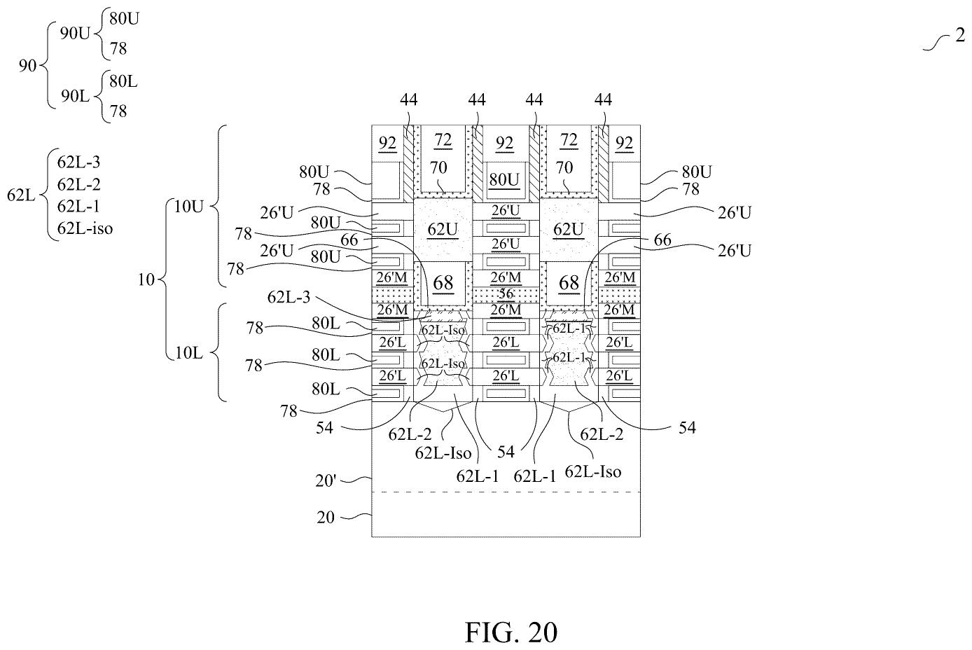

Replacement gate stacks 90 (including gate stacks 90L and 90U) are formed in the respective recesses, as shown in FIG. 20. CFET 10 is thus formed. The formation of the replacement gate stacks 90 may be essentially the same as discussed referring to FIG. 16, and are not repeated herein.

FIGS. 21 through 26 illustrate the cross-sectional views of intermediate stages in the formation of a CFET in accordance with some embodiments of the present disclosure. These embodiments are similar to the embodiments as shown in FIGS. 1 through 16, except that the lower source/drain regions 62L are formed using different processes than in the preceding embodiments. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

The initial steps of these embodiments are essentially the same as shown in FIGS. 2 through 5. The resulting structure is also shown in FIG. 21, which is essentially the same as the structure shown in FIG. 5.

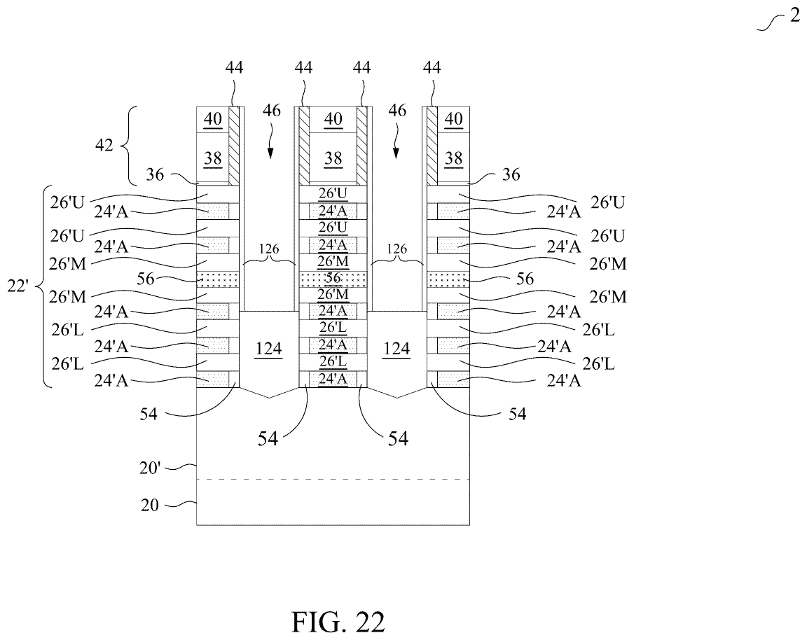

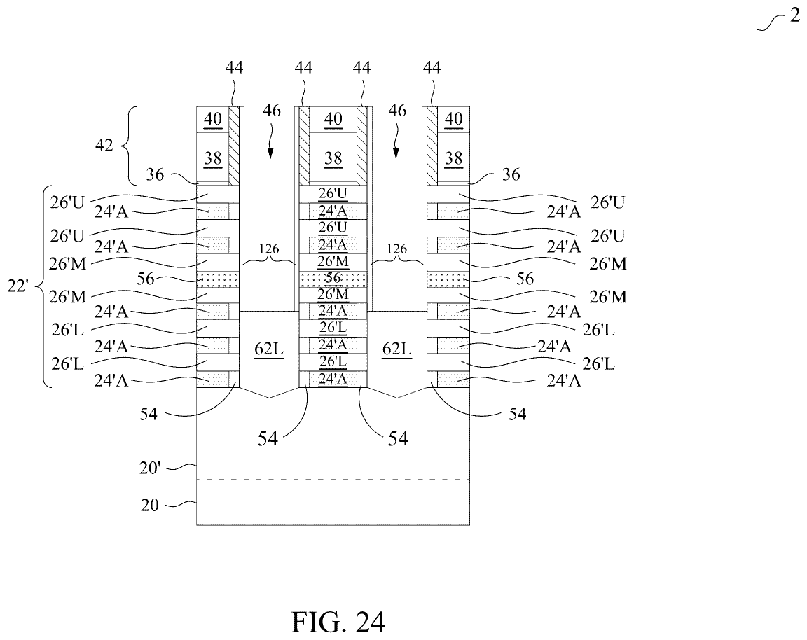

Next, as shown in FIG. 22, sacrificial regions 124 are formed to fill the bottom parts of source/drain recesses 46. The sizes of the sacrificial regions 124 may be essentially the same as the sizes of the lower source/drain regions 62L (FIG. 24) that are to be formed in subsequent processes. The formation of the sacrificial regions 124 may include depositing a sacrificial layer fully filling source/drain recesses 46, planarizing the sacrificial layer (for example, through CMP or mechanical grinding), and etching back the sacrificial layer. The sacrificial layer may comprise a photoresist or a polymer, which may be, or may not be photo sensitive.

Next, dielectric liners 126 are formed. The formation process may include performing a conformal deposition process to form a conformal dielectric layer. The conformal dielectric layer extends into the source/drain recesses 46. An anisotropic etching process is then performed to etch the conformal dielectric layer, so that horizontal portions of the conformal dielectric layer are removed, leaving vertical portions of the conformal dielectric layer as the dielectric liners 126. Dielectric liners 126 may be formed of or comprise silicon oxide, silicon nitride, silicon oxynitride, silicon oxy-carbo-nitride, silicon carbide, or the like, or combinations thereof.

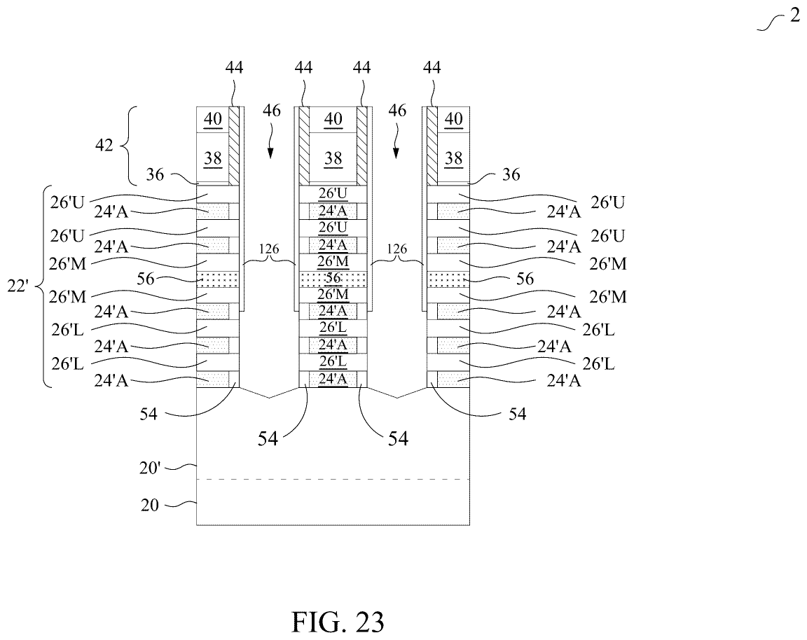

The sacrificial regions 124 are then removed, for example, through etching, so that the sidewalls of lower semiconductor nanostructures 26′L are exposed. The resulting structure is shown in FIG. 23.

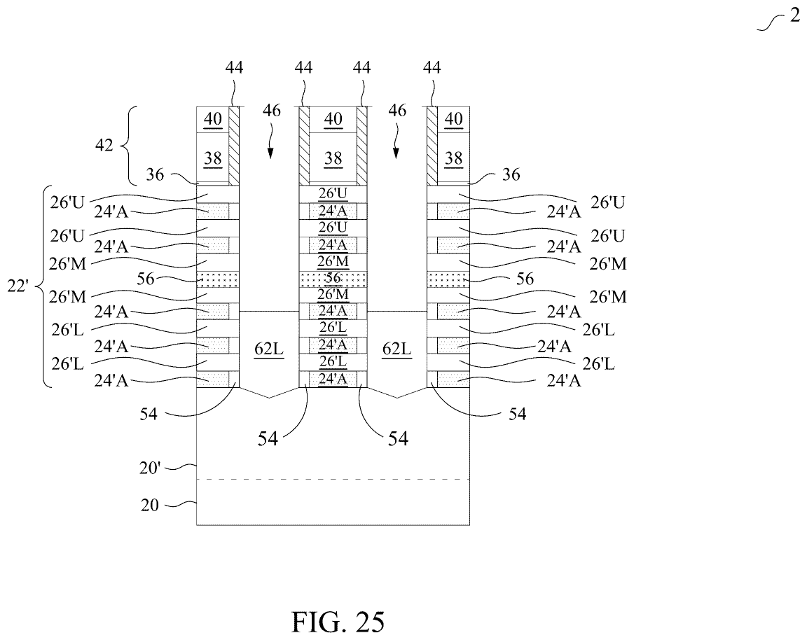

Next, as shown in FIG. 24, lower source/drain regions 62L are selectively formed starting from the exposed lower semiconductor nanostructures 26′L. A etching gas may be added, so that the lower source/drain regions 62L are formed at positions lower than the dielectric liners 126, and are not grown starting from dielectric materials such as dielectric liners 126. Dielectric liners 126 are then removed, and the resulting structure is shown in FIG. 25.

Subsequently, the processes as shown in FIGS. 13A and 13B through FIG. 16 are performed to form dielectric film 116, CESL 70A and ILD 72A, upper source/drain regions 62U, and CESL 70B and ILD 72B. The details of the processes, materials, and structures may be found in the discussion referring to FIGS. 13A and 13B through FIG. 16, and are not repeated herein.

The embodiments of the present disclosure have some advantageous features. In accordance with some embodiments, in the formation of the lower source/drain regions, bottom-up epitaxy, etching back processes, and the controlling of etching-to-deposition rate ratios may be combined to prevent the epitaxy of semiconductor material on the sidewalls of the upper semiconductor nanostructures 26′U. This saves the effort of depositing dielectric liners, filling source/drain recesses with a dummy material, performing a CMP process and an etching process, and removing the dielectric liner. The embodiments of the present disclosure require less-precise process control, and may help to avoid the loss of inner spacers, shorting, and leakages.

Furthermore, in accordance with some embodiments, the formation of upper source/drain regions, CESLs, and ILDs may be performed by forming a dielectric film on the lower source/drain regions, so that upper source/drain regions may be formed before the formation of the lower CESLs and ILDs. The lower CESLs and upper CESLs may be formed simultaneously, and the lower ILDs and upper ILDs may be formed simultaneously. By adopting these embodiments, the multiple process steps such as depositing and planarizing the lower CESLs and lower ILDs, and etching back the lower CESLs and lower ILDs, etc. are avoided. The problems associated with these processes such as the loss of inner spacers, leakages between gate and source drains, etc., are avoided or reduced.

In accordance with some embodiments of the present disclosure, method comprises forming a lower semiconductor nanostructure and an upper semiconductor nanostructure over and spaced apart from the lower semiconductor nanostructure; forming a lower source/drain region comprising performing a first epitaxy process to grow a first semiconductor isolation layer and a second semiconductor isolation layer, wherein the first semiconductor isolation layer is grown from the lower semiconductor nanostructure, and the second semiconductor isolation layer is grown from the upper semiconductor nanostructure; and performing a second epitaxy process to grow an epitaxy semiconductor layer from the first semiconductor isolation layer, wherein the second epitaxy process comprises a bottom-up deposition process; etching the second semiconductor isolation layer to expose a sidewall of the upper semiconductor nanostructure; forming an upper source/drain region starting from the upper semiconductor nanostructure; and after the upper source/drain region is formed, forming a first contact etch stop layer and a first inter-layer dielectric in a space between the lower source/drain region and the upper source/drain region.

In an embodiment, when the second semiconductor isolation layer is etched, a top surface of the lower source/drain region is exposed. In an embodiment, during an entire period of time the lower source/drain region is formed, no dielectric liner is formed to contact the upper semiconductor nanostructure.

In an embodiment, the method further comprises forming a dielectric isolation layer between the lower semiconductor nanostructure and the upper semiconductor nanostructure; forming a dielectric inner spacer overlapped by the upper semiconductor nanostructure, wherein the dielectric inner spacer is aside of and contacting a dummy semiconductor layer, and wherein the dielectric isolation layer has a greater oxygen atomic percentage than the dielectric inner spacer; and replacing the dummy semiconductor layer with a replacement gate stack.

In an embodiment, during epitaxy processes for forming the lower source/drain region, semiconductor materials of the lower source/drain region have a lower growth rate on the dielectric isolation layer than on the dielectric inner spacer. In an embodiment, the method further comprises performing a plasma treatment process to form a dielectric film over the lower source/drain region, wherein at a starting time and a finishing time of the plasma treatment process, the sidewall of the upper semiconductor nanostructure is exposed.

In an embodiment, the plasma treatment process is performed using a process gas comprising oxygen. In an embodiment, the plasma treatment process is performed using a process gas comprising nitrogen. In an embodiment, the method further comprises forming a second contact etch stop layer and a second inter-layer dielectric over the upper source/drain region, wherein the first contact etch stop layer and the second contact etch stop layer are formed in a first common deposition process. In an embodiment, the first inter-layer dielectric and the second inter-layer dielectric are formed in a second common deposition process.

In accordance with some embodiments of the present disclosure, method comprises forming a lower semiconductor nanostructure and an upper semiconductor nanostructure over and spaced apart from the lower semiconductor nanostructure; forming a lower source/drain region contacting the lower semiconductor nanostructure; forming an upper source/drain region contacting the upper semiconductor nanostructure, wherein the upper source/drain region is spaced apart from the lower source/drain region by a space; and after the upper source/drain region is formed, forming a first contact etch stop layer and a first inter-layer dielectric in the space.

In an embodiment, when the upper source/drain region is formed, the upper source/drain region is suspended over the space. In an embodiment, the method further comprises, at a time after the lower source/drain region is formed and before the upper source/drain region is formed, forming a dielectric film over the lower source/drain region. In an embodiment, the forming the dielectric film comprises a plasma treatment process. In an embodiment, the plasma treatment process is performed using a process gas selected from the group consisting of an oxygen-comprising process gas, a nitrogen-comprising process gas, and combinations thereof.

In an embodiment, the method further comprises forming a second contact etch stop layer and a second inter-layer dielectric over the upper source/drain region, wherein the first contact etch stop layer and the second contact etch stop layer are formed simultaneously; and the first inter-layer dielectric and the second inter-layer dielectric are formed simultaneously.

In accordance with some embodiments of the present disclosure, structure comprises a lower transistor comprising a lower source/drain region; a first contact etch stop layer over and contacting the lower source/drain region; a first inter-layer dielectric, wherein in a cross-sectional view of the structure, the first contact etch stop layer has a ring-shape encircling the first inter-layer dielectric; an upper transistor comprising an upper source/drain region, wherein the upper source/drain region overlaps the first contact etch stop layer and the first inter-layer dielectric; a second contact etch stop layer over the upper source/drain region; a second inter-layer dielectric over the second contact etch stop layer; and gate spacers on opposing sides of the second contact etch stop layer.

In an embodiment, the first contact etch stop layer comprises a same first dielectric material as the second contact etch stop layer, and the first inter-layer dielectric comprises a same second dielectric material as the second inter-layer dielectric. In an embodiment, the structure further comprises a dielectric film between the lower source/drain region and the first contact etch stop layer. In an embodiment, the first contact etch stop layer comprises a bottom portion contacting the dielectric film, and a top portion underlying and contacting the upper source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a lower semiconductor nanostructure and an upper semiconductor nanostructure over and spaced apart from the lower semiconductor nanostructure;
forming a lower source/drain region comprising:
performing a first epitaxy process to grow a first semiconductor isolation layer and a second semiconductor isolation layer, wherein the first semiconductor isolation layer is grown from the lower semiconductor nanostructure, and the second semiconductor isolation layer is grown from the upper semiconductor nanostructure; and
performing a second epitaxy process to grow an epitaxy semiconductor layer from the first semiconductor isolation layer, wherein the second epitaxy process comprises a bottom-up deposition process;
etching the second semiconductor isolation layer to expose a sidewall of the upper semiconductor nanostructure;
forming an upper source/drain region starting from the upper semiconductor nanostructure; and
after the upper source/drain region is formed, forming a first contact etch stop layer and a first inter-layer dielectric in a space between the lower source/drain region and the upper source/drain region.

2. The method of claim 1, wherein when the second semiconductor isolation layer is etched, a top surface of the lower source/drain region is exposed.

3. The method of claim 1, wherein during an entire period of time the lower source/drain region is formed, no dielectric liner is formed to contact the upper semiconductor nanostructure.

4. The method of claim 1 further comprising:
forming a dielectric isolation layer between the lower semiconductor nanostructure and the upper semiconductor nanostructure;
forming a dielectric inner spacer overlapped by the upper semiconductor nanostructure, wherein the dielectric inner spacer is aside of and contacting a dummy semiconductor layer, and wherein the dielectric isolation layer has a greater oxygen atomic percentage than the dielectric inner spacer; and
replacing the dummy semiconductor layer with a replacement gate stack.

5. The method of claim 4, wherein during epitaxy processes for forming the lower source/drain region, semiconductor materials of the lower source/drain region have a lower growth rate on the dielectric isolation layer than on the dielectric inner spacer.

6. The method of claim 1 further comprising performing a plasma treatment process to form a dielectric film over the lower source/drain region, wherein at a starting time and a finishing time of the plasma treatment process, the sidewall of the upper semiconductor nanostructure is exposed.

7. The method of claim 6, wherein the plasma treatment process is performed using a process gas comprising oxygen.

8. The method of claim 6, wherein the plasma treatment process is performed using a process gas comprising nitrogen.

9. The method of claim 1 further comprising forming a second contact etch stop layer and a second inter-layer dielectric over the upper source/drain region, wherein the first contact etch stop layer and the second contact etch stop layer are formed in a first common deposition process.

10. The method of claim 9, wherein the first inter-layer dielectric and the second inter-layer dielectric are formed in a second common deposition process.

11. A method comprising:
forming a lower semiconductor nanostructure and an upper semiconductor nanostructure over and spaced apart from the lower semiconductor nanostructure;
forming a lower source/drain region contacting the lower semiconductor nanostructure;
forming an upper source/drain region contacting the upper semiconductor nanostructure, wherein the upper source/drain region is spaced apart from the lower source/drain region by a space; and
after the upper source/drain region is formed, forming a first contact etch stop layer and a first inter-layer dielectric in the space.

12. The method of claim 11, wherein when the upper source/drain region is formed, the upper source/drain region is suspended over the space.

13. The method of claim 11 further comprising, at a time after the lower source/drain region is formed and before the upper source/drain region is formed, forming a dielectric film over the lower source/drain region.

14. The method of claim 13, wherein the forming the dielectric film comprises a plasma treatment process.

15. The method of claim 14, wherein the plasma treatment process is performed using a process gas selected from the group consisting of an oxygen-comprising process gas, a nitrogen-comprising process gas, and combinations thereof.

16. The method of claim 11 further comprising forming a second contact etch stop layer and a second inter-layer dielectric over the upper source/drain region, wherein:
the first contact etch stop layer and the second contact etch stop layer are formed simultaneously; and
the first inter-layer dielectric and the second inter-layer dielectric are formed simultaneously.

17. A structure comprising:
a lower transistor comprising a lower source/drain region;
a first contact etch stop layer over and contacting the lower source/drain region;
a first inter-layer dielectric, wherein in a cross-sectional view of the structure, the first contact etch stop layer has a ring-shape encircling the first inter-layer dielectric;
an upper transistor comprising an upper source/drain region, wherein the upper source/drain region overlaps the first contact etch stop layer and the first inter-layer dielectric;
a second contact etch stop layer over the upper source/drain region;
a second inter-layer dielectric over the second contact etch stop layer; and
gate spacers on opposing sides of the second contact etch stop layer.

18. The structure of claim 17, wherein the first contact etch stop layer comprises a same first dielectric material as the second contact etch stop layer, and the first inter-layer dielectric comprises a same second dielectric material as the second inter-layer dielectric.

19. The structure of claim 17 further comprising a dielectric film between the lower source/drain region and the first contact etch stop layer.

20. The structure of claim 19, wherein the first contact etch stop layer comprises a bottom portion contacting the dielectric film, and a top portion underlying and contacting the upper source/drain region.
